(19) United States
(12) Patent Application Publication
(10) Pub. No.: US 2026/0095129 A1
(43) Pub. Date: Apr. 2, 2026

(54) MONITORING OF INDUCTOR BEHAVIOR

(71) Applicant: Cirrus Logic International Semiconductor Ltd., Edinburgh (GB)

(72) Inventors: John P. LESSO, Edinburgh (GB); John L. MELANSON, Austin, TX (US)

(73) Assignee: Cirrus Logic International Semiconductor Ltd., Edinburgh (GB)

(21) Appl. No.: 18/899,579

(22) Filed: Sep. 27, 2024

(51) Int. Cl. H03F 1/32; G01R 27/26; H03F 3/217

(52) U.S. Cl. CPC H03F 1/32; G01R 27/2611; H03F 3/217; H03F 2200/117

(57) ABSTRACT

This application relates to methods and apparatus for compensating for distortion in an output drive signal of a switched-mode amplifier which arises from non-linearity of an inductor in an output path for the drive signal. A distortion predictor is configured to predict the distortion in the output drive signal. The distortion predictor has a current predictor configured to determine a predicted current in the inductor based on, at least, an indication of an input voltage for the inductor. A model then models the distortion based on the predicted current and a corrector determines a correction term based on the predicted distortion that can be additively applied to an input signal to at least partly compensate for the distortion in the drive signal.

### FIELD OF DISCLOSURE

The field of representative embodiments of this disclosure relates to methods, apparatus and/or implementations concerning or relating to monitoring of behaviour of inductors, especially of an inductor in a switched-mode driver circuit, and, in particular, to determining and/or compensating for any non-linearity due to the inductor.

### BACKGROUND

Class-D amplifiers, also referred to as switching or switched-mode drivers or amplifiers, are used in a variety of applications for driving load transducers, such as audio output transducers or the like, and can have advantages in terms of power efficiency compared to linear amplifiers. Class-D amplifiers typically comprise a modulator circuit for receiving an input signal and generating a suitably modulated signal, e.g. a PWM (pulse-width-modulation) signal for controlling a switching output stage, which may, or may not, be integrated with the modulator. The modulated signal controls the output stage to modulate the one or more output nodes between different voltages with a controlled duty-cycle, so as to generate a desired voltage, on average over one or more switching cycles. The class-D amplifier may, in at least some applications, be implemented to operate in a closed-loop manner and thus the modulator may receive feedback from downstream of the output stage and may use the feedback signal to correct for errors introduced by the modulator and output stage.

In at least some applications, in particular for relatively high-power applications and/or in applications where there may be a relatively long output path between the output stage and the load, such as automotive or home theatre applications, there may be an output filter for filtering applying filtering to the output of the amplifier so as to provide the drive signal for the load. Such an output filter may typically be implemented by an inductance-capacitance (LC) filter, with a series inductance in the output path and a shunt capacitance to a defined voltage, such as ground. Because of the significant delay introduced by the output filter, using the drive signal which has been filtered by the output filter as the feedback signal is problematic and thus, conventionally, the feedback signal is tapped from upstream of the output filter. As such the closed-loop operation does not correct for any errors introduced into the drive signal by the output filter.

Embodiments of the present disclosure relate to methods and apparatus for modulators for class-D amplifiers and the like that at least mitigate at least some of above-mentioned issues.

### SUMMARY

According to an aspect of the disclosure there is provided an apparatus for compensating for distortion in an output drive signal of a switched-mode amplifier which arises from non-linearity of an inductor in an output path for the drive signal. The apparatus comprises a distortion predictor configured to predict the distortion in the output drive signal. The distortion predictor comprises a current predictor, configured to determine a predicted current in the inductor based on at least an indication of an input voltage for the inductor, and a model, for modelling the distortion based on the predicted current. A corrector is configured to determine a correction term based on the predicted distortion that can be additively applied to an input signal to at least partly compensate for the distortion in the drive signal.

In some examples, the indication of an input voltage for the inductor may be based on a received input signal for the switched-mode amplifier system. The current predictor may be configured to determine a predicted current in the inductor based on the indication of an input voltage for the inductor and an indication of an output voltage for the inductor. The indication of an input voltage for the inductor may be a feedback signal from an input to the inductor and the indication of an output voltage for the inductor may be a feedback signal from an output of the inductor. In some examples, the indication of an input voltage for the inductor may be based on a received input signal for the switched-mode amplifier system and the indication of an output voltage for the inductor may be a feedback signal from an output of the inductor.

The current predictor may be configured to determine the predicted current based on a integral of a voltage difference between the input voltage for the inductor the output voltage for the inductor and an estimate of an inductance of the inductor. The current predictor may be configured to determine the predicted current based on the integral of the voltage difference for a first frequency range and may be configured to determine the predicted current based on a feedback signal of a measured average of inductor current for a second, lower, frequency range. The current predictor may, in some examples, comprise a leaky integrator.

In some examples, the model may be configured to determine a magnetic field strength of the inductor from the predicted current and to determine a magnetic flux density of the inductor from the magnetic field strength and to update the estimate of the inductance of the inductor. The inductor may be part of an inductance-capacitance filter with a capacitor and the model may be configured to determine a capacitor current through the capacitor and integrate the capacitor current to determine a predicted filter output signal. the model may be configured to also model non-linearity of the capacitor.

In some examples, the current predictor may be further configured to determine a predicted current in the inductor based on a feedback signal of a measured average of inductor current.

In some examples, the corrector may be configured to determine the correction term as a polynomial correction term and wherein an order of the polynomial correction term is selectively configurable.

In some examples, the model may be dynamically adapted.

Aspects also relate to an amplifier system comprising the apparatus for compensating ode distortion according to any of the embodiments described herein, and the switched-mode amplifier.

In another aspect, there is provided an apparatus for compensating for distortion in an output drive signal of a switched-mode amplifier which arises from non-linearity of an inductor in an output path for the drive signal. The apparatus comprises: a distortion predictor configured to predict the distortion in the output drive signal; and a corrector configured to determine a correction term based on the predicted distortion that can be additively applied to an input signal to at least partly compensate for the distortion in the drive signal.

In some examples, the distortion predictor may comprise a current predictor configured to determine a predicted current in the inductor. The current predictor may be configured as a closed-loop current predictor which receives at least a feedback signal of an output voltage of the inductor.

In another aspect, there is provided a predictor for predicting a current in an inductor, the current predictor comprising a leaky integrator configured to integrate an indication of a voltage across the integrator and a divider for dividing the output of the integrator by an estimate of an inductance of the inductor.

The predictor may be configured to receive an indication of an input voltage for the inductor and an indication of an output voltage for the inductor and determine said indication of a voltage across the integrator. The indication of an output voltage for the inductor may comprise a feedback signal of a monitored output of the inductor. The indication of an input voltage for the inductor may comprise a feedback signal of a monitored input of the inductor.

It should be noted that, unless expressly indicated to the contrary herein or otherwise clearly incompatible, then any feature described herein may be implemented in combination with any one or more other described features.

### BRIEF DESCRIPTION OF THE DRAWINGS

For a better understanding of examples of the present disclosure, and to show more clearly how the examples may be carried into effect, reference will now be made, by way of example only, to the following drawings in which:

FIG. 1 illustrates one example of a conventional class-D amplifier system;

FIG. 2 illustrates one example of a class-D amplifier system according to an embodiment;

FIG. 3 illustrates one example of a predictor for predicting distortion in an LC filter; and

FIG. 4 illustrates the principles of predicting current for different frequency regions.

### DETAILED DESCRIPTION

The description below sets forth example embodiments according to this disclosure. Further example embodiments and implementations will be apparent to those having ordinary skill in the art. Further, those having ordinary skill in the art will recognize that various equivalent techniques may be applied in lieu of, or in conjunction with, the embodiments discussed below, and all such equivalents should be deemed as being encompassed by the present disclosure.

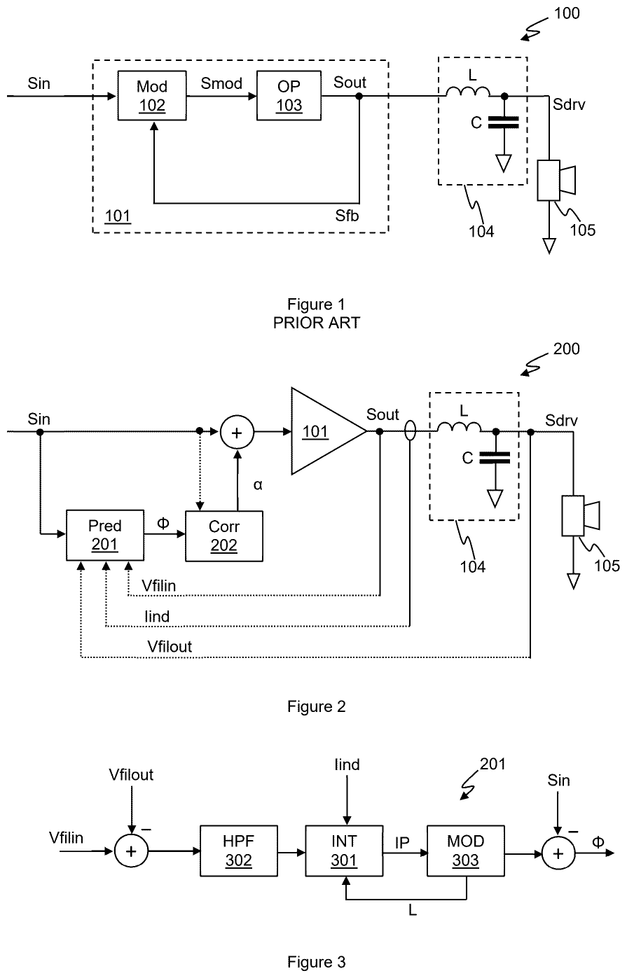

FIG. 1 illustrates one example of a conventional class-D amplifier system 100. The amplifier system 100 has an amplifier 101 comprising a modulator 102, which may for instance comprise a PWM modulator, configured to generate a modulated signal Smod based on an input signal Sin. The modulated signal Smod controls switching of a switching output stage 103, which may or may not be formed as part of an integrated circuit with the modulator 102, to generate an output signal Sout at an output node of the amplifier 101 which is modulated between different switching voltages with a controlled duty-cycle. In some implementations, there may be just two switching voltages, e.g. a high switching voltage and low switching voltage, but in other multi-level implementations there may be more than two different voltages that can selectively be used as switching voltages.

The output signal Sout is filtered by output LC (inductor-capacitor) filter 104 to provide a drive signal Sdrv for driving a load 105, which may be a transducer, such as loudspeaker for audio applications. Note, FIG. 1 illustrates the amplifier driving the load 105 in a single ended configuration, but in some applications the amplifier may be configured to drive the load connected between two output nodes in a bridge-tied-load configuration, with each output node being modulated between selected voltages with a controlled duty-cycle.

It is common for such a class-D amplifier system 100 to be operable in a closed-loop mode of operation in which a feedback signal Sfb is fed back to the modulator 102 to correct for at least some errors in generation of the drive signal Sdrv as part of a control loop. For instance, as will be understood by one skilled in the art the feedback signal Sfb may be subtracted from a feedforward version of the input signal to generate an error signal that may be filtered by a loop filter and used to apply a compensation to the input signal, although other control loop arrangements could be implemented.

Were the feedback signal to be a version of the drive signal Sdrv, e.g. tapped from near the load, the compensation applied by means of the feedback could, in theory, correct for any inaccuracies introduced by the modulation, the operation of the output stage and any inaccuracies due to the output path including the output LC filter 104. However, the operation of the output LC filter 104 introduces a delay into the drive signal which is significant from the perspective of the control loop of the amplifier and which means it is practically challenging to design a high performance control loop. Generally, therefore, the presence of the filter delay may result in a relatively low loop gain being used, which limits the ability of the control loop to compensate for errors.

For practical performance reasons, the feedback signal Sfb may, therefore, be tapped from downstream of the output stage 103 but upstream of the output LC filter 104. As such the control loop of the amplifier 101 may satisfactorily compensate for any errors introduced by operation of the output stage 103, but any errors introduced by the output filter 104 cannot be corrected by the control loop.

One source of error that can be introduced by the output filter arises due to non-linearity of the series inductor of the LC filter. Practical inductors are generally implemented by an electrical path winding around a magnetic core material and have a BH curve which is non-linear, i.e. the relationship between the magnetic flux density B and magnetic field strength H is non-linear. As current in the electric windings increases, the magnetic field strength H and magnetic flux density B increase, but the non-linear BH curve means that the effective inductance varies, and typically drops with increasing current. This leads to a non-linearity in inductor current and hence a distortion in the drive signal Sdrv.

At least some embodiments of the present disclosure relate to methods and apparatus for, at least partly, compensating for such distortion arising from non-linearity of a series inductor, in particular as part of an LC filter.

There are two particular challenges that apply when attempting to compensate for non-linearity of an LC filter. The first is that the non-linearity or distortion is applied to the inductor current which is out of phase with the output voltage. For the inductor, the current is the key variable whereas for the filter capacitor, voltage is key. The second is that the non-linearity depends on the operating point on the BH curve of the inductor, which is a function of the signal content and ripple current in the inductor. The relevant operating point on the BH curve should be known to be able to apply the correct compensation.

One approach that has previously been generally proposed for compensating for unwanted distortion in a signal path is to determine the relevant transfer function of the distortion and then apply the inverse of that transfer function at an appropriate point in the signal path, which may be upstream of the unwanted distortion, i.e. to apply a deliberate pre-distortion to the signal, so that when it is subsequently subjected to the unwanted distortion, the resultant signal is correct. This could, for example, be performed by finding an appropriate polynomial that describes the transfer function of the distortion and then inverting it. However, whilst this approach can work for distortions that are generally low-order and well behaved, the distortion of an inductor in an LC filter, is not low order and well behaved and the phase difference between inductor current and capacitor voltage make determining a suitable polynomial very challenging.

In addition, if it is desirable for the compensation to be adaptive to changes in some parameters, determining the relevant compensation in real time requires inversion of the determine transfer function of the distortion. Inversion is a generally complex and computationally intensive operation.

At least some embodiments of the present disclosure thus involve modelling the distortion of the LC filter, i.e. the non-linearity arising due to the inductor of the filter, and then compensating for the distortion by an additive process, i.e. determining a correction term that can be applied to the signal without requiring any inversion.

The distortion p(x) in the output drive signal Sdrv can be modelled as the sum of this input signal, represented as x and an additive error function φ(x):

$$p ( x ) = x + ϕ ( x ) \qquad Eqn . 1$$

where φ(x) is small relative to x. A correction term α, i.e. a suitable correction function such as a polynomial correction function, can then be defined such that:

$$p ( x + α ) \approx x \qquad Eqn . 2$$

The function p(x+α) can be written as:

$$p ( x + α ) = ( x + α ) + ϕ ( x + α ) \qquad Eqn . 3$$

For p(x) to be equal to x then:

$$x + α + ϕ ( x + α ) = x \qquad Eqn . 4$$

which simplifies to:

$$α + ϕ ( x + α ) = 0 \qquad Eqn . 5$$

Equation 5 can be regarded as the characteristic equation for the correction and the equation can be solved to an arbitrary degree of accuracy. For instance, the zeroth order solution can be given as α=−φ(x). Higher order solutions can be obtained by expanding φ(x+α) using, for instance, a Taylor series of the relevant order, which can be added into equation 5 and solved for α. For example, a first order solution for the correction term α can be given by:

$$α = - \frac{ϕ ( x )}{1 + {ϕ}^{′} ( x )} \qquad Eqn . 6$$

In this way, a correction term can be determined for the distortion in the output drive signal, without requiring a computationally expensive inversion operation.

Note that it is not necessarily the case that such an approach to determining an additive error term and suitable correction term would be possible or practical, but simulation and testing has shown that it is possible to determine and correct for distortion of an LC filter in such a manner and the determination and/or use of an additive correction term to correct for distortion of an LC filter represents one novel aspect of this disclosure.

To determine the error term φ(x), a predictor can be used to model the non-linear behavior of the output filter for a given input signal and predict the distortion. A corrector may then determine the relevant correction term α which can be applied to the signal path so as to, at least partly, pre-correct for the errors introduced by the LC output filter 103.

FIG. 2 illustrates one example of an amplifier system 200 according to an embodiment. A switched-mode amplifier 101, which may for instance be the same type of amplifier as discussed with reference to FIG. 1, is configured to receive an input signal Sin and output a modulated output signal Sout, which is filtered by output LC filter 104 to provide a drive signal for driving a load 105 in a similar manner as discussed with reference to FIG. 1. The amplifier 101 may be a digital amplifier 101 which receives a digital input signal or an analog amplifier 101 configured to receive an analog input, in which case the amplifier may have an input digital-to-analog converter (not illustrated).

In the amplifier system 200, a predictor 201 is configured to receive the input signal and to generate a prediction of the error term @ (x) that would be expected in the drive signal Sdrv with no compensation. A corrector 202 receives the prediction of the error term φ(x) and determines an appropriate additive correction term α that can be applied as an additive correction to the input signal for the amplifier 101. In this way the distortion in the drive signal Sdrv can be reduced or eliminated. Preferably the predictor 201 and corrector 202 are implemented in the digital domain and thus operate on a digital version of the input signal Sin.

The model used by the predictor may, in some embodiments, be implemented as a physics-based model of the operation of the LC filter.

FIG. 3 illustrates one general example of predictor which uses physics-based model of the operation of the LC filter. The predictor 201 in the example of FIG. 3 is configured to receive an indication of the voltage of the output signal Sout, which represents the voltage Vfilin which is input to the LC filter 104, and also an indication of the voltage of the drive signal Sdrv, which represents the voltage Vfilout which is output from the LC filter 104, and determine a prediction IP of inductor current, based on the relationship:

$$V ( t ) = L \frac{di}{dt} \qquad Eqn . 7$$

The prediction IP of inductor current may thus be determined by determining the voltage difference between the Vfilin which is input to the LC filter 104 and the voltage Vfilout which is output from the LC filter 104, i.e. Vfilin-Vfilout, and then integrating the difference in an integrator 301 which also applies a division based on an estimate L of the inductance of the inductor. This may be achieved by performing a leaky integration as will be understood by one skilled in the art and thus the integrator 301 may be a leaky integrator. The integration can effectively provide the desired phase shift between voltage and current, and thus the integrator can provide a good estimate of the inductor current for the frequency range over which it provides integration, i.e. for frequencies above the pole of the integrator. For low frequencies, however, e.g. below the pole of the integrator, the resultant estimate based on the voltage difference across the inductor may not be a good estimate of the inductor current. The input to the leaky integrator 301 may thus be high-pass filtered by high-pass filter 302 to remove low frequencies and the leaky integrator 301 may be configured such that a pole of the leaky integrator 301 is below the frequency cut-off of the high-pass filter 302. For low frequencies, a measure of the actual inductor current Ind, which may be a low-pass filtered version of the measured current, could be used directly as the predicted current IP for this frequency range. The measure of inductor current Ind can thus be added to the estimate provided by the integrator, with the amount of the leak being based on the measured current to provide numerical stability.

Adding a low pass filtered version of the inductor current Ind can ensure operation at the correct DC operating point of the BH curve. It will be understood that the average inductor current over the switching cycle will have a dependence on the input signal Sin, but that there the inductor current will vary in any given switching cycle due to the high-frequency modulation of the output signal Sout, and this will lead to an inductor ripple current. The part of the BH curve explored by the ripple current variation with depend on the relevant DC operating point due to the average inductor current, but the effective shape of the BH curve as seen for the baseband signal will depend on the extent of the ripple current. The model can thus take both signal dependent baseband current and ripple current into account when determining the non-linearity.

Thus, the estimated inductor current may be generated such that, for a higher frequency range, e.g. above the pole of the integrator, the integrated voltage is the dominant signal component of the estimated current, whereas for a lower frequency range the measured current is the dominant signal component of the estimated current.

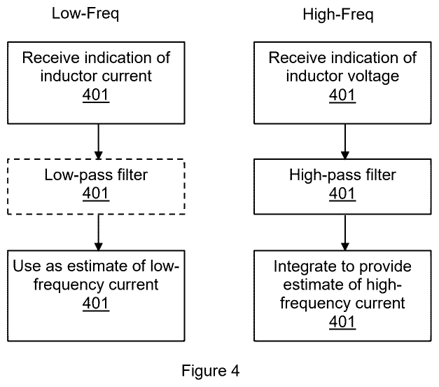

In general, therefore, as illustrated in FIG. 4, the predictor may operate in different ways in a high-frequency region and a low-frequency region. In the high frequency region an indication of the inductor voltage is received, e.g. Vfilin-Vfilout, and high-pass filtered and integrated to provide the estimate of inductor current in the high-frequency region. For the low-frequency region, a measure of inductor current may be received and filtered if necessary and the low-pass used as the estimate of inductor current for the low frequency region. Such operation can be conveniently achieved by use a leaky integrator as discussed above, where the leak is to the measured current.

The leaky integrator 301 can be implemented by a suitable digital leaky integrator. The sample rate for the leaky integrator may be set to provide a suitable trade-off between computational efficiency, which favours a lower sample rate, and frequency range for which the leaky integrator operates as an integrator and provides the desired phase shift, which is greater at higher sample rates, i.e. a faster sample rate can lead to a lower cutoff for the high-frequency region.

Referring back to FIG. 3, the predicted current IP is then passed to the model 303 that models the behaviour of the inductor based on the predicted current and relevant parameters of the output LC filter 104.

The model 303 may determine a value of magnetic field strength H from the estimate or measurement of inductor current, and relevant parameters for the inductor, e.g. the number N of the inductor windings and cross section area A. The model 303 may then determine the magnetic flux density B from the value of the magnetic field strength H using a suitable model of magnetic hysteresis. For instance, the magnetic flux density B may be determined from the value of the magnetic field strength H using the known Jiles-Atherton model as would be understood by one skilled in the art, although other hysteresis models could be used.

An updated estimate of the effective inductance of the inductor could then be determined from the derivatives of H and B, with the updated estimate of inductance being used by the leaky integrator 301.

This approach allows a determination of the current through the capacitor of the output filter, which can be integrated the provide an indication of the filter output voltage, i.e. the voltage of the drive signal Sdrv in this example, from which the predicted distortion or error term @ (x) can be determined.

Using such an approach, the predictor 201 can model the behaviour of a non-linear inductor in an LC low pass filter, taking the BH curve for the inductor into account.

However, it should be noted that the model could be a machine learning model, e.g. an artificial neural network or the like, that learns the relevant distortion. For instance, a neural network comprising an input non-linear layer and a multi-layer perceptron (MLP) could be implemented to provide the model.

In practical implementations, however, it may be beneficial for the model to be adapted in use, for instance to take account of changing parameters. For instance, temperature may have an effect, so temperature may be monitored and fed into the model. The load impedance also has an effect, so the amplifier system may also be configured to determine load impedance. Aging may have an impact on the various component of the filter and require a change in the relevant parameters of the model.

However, retraining of a machine learning model can be relatively computationally expensive, and thus there may be advantages in implementing a physics-based model along the lines described in at least some embodiments.

In embodiments where the model is adapted in use, the model could be adapted directly or, alternatively, there could be a main model which is used by the predictor 201 to determine the non-linearity and an auxiliary model (not separately illustrated). The parameters of the auxiliary model could be adaptively updated on an ongoing basis, with the parameters of the auxiliary model being occasionally used to update the main model. This can avoid overly frequent updating of the main model. The main model may be updated on a regular periodic basis and/or in an event driven manner, e.g. if some tolerance measure is exceeded and/or based on appropriate operating conditions for updating the main model without artefacts.

The adaptation may be based on a comparison of the predicted current and the measured current. In general, the aim is to ensure the predicted current and measured current match as closely as possible, or at least to within a certain tolerance. The parameters of the model, preferably the auxiliary model outside of the main loop, may thus be updated to minimise any difference in the predicted current and measured current, e.g. using a least squares approach or similar. Once the updated model parameters have been determined, they can be copied to the main model as discussed above.

As discussed above, the predictor 201 may thus receive an indication of the voltage of voltage of the output signal Sout, which represents the voltage Vfilin which is input to the LC filter 104, and also an indication of the voltage of the drive signal Sdrv, which represents the voltage Vfilout which is output from the LC filter 104, along with an indication of the measured inductor current lind. The predictor 201 may thus be implemented in a closed-loop arrangement which is configured to receive the relevant feedback signals.

Given the predictor 201 will preferably be implemented in the digital domain, this does however potentially require dedicated ADCs for each of these three feedback signals, although in some cases a digital version of at least one of relevant feedback signals may be useful for some other function of the amplifier system and thus a relevant ADC may be present for some other circuit function.

In some applications, it may be assumed that the output signal Sout will sufficiently correspond to the input signal Sin (with the expected gain) such that the input signal Sin can be used as the indication of the output signal Sout and hence used to provide the indication of the voltage Vfilin which is input to the LC output filter 104. In particular, if the amplifier 101 is implemented as a closed-loop amplifier such as discussed with reference to FIG. 1, it may be assumed that the closed-loop operation of the amplifier 101 will substantially correct for errors of the output stage 103 and thus Sout with be a sufficiently correct representation of Sin.

In some applications, the indication of the measured inductor current lind could be omitted, i.e. the predictor 201 may not receive a feedback signal of lind, so as to reduce the number of ADCs required for the predictor 201. In such a case, the predictor 201 may just receive the indication of the filter output voltage Vfilout, i.e. the feedback signal from Sdrv, with Sin being used as the indication of the input voltage for the LC output filter 104. The reduced number of ADCs required for the predictor is advantageous in terms of lowering circuit area and cost, but the lack of the indication of the measured inductor current lind can mean that there are no DC stability points on the BH curve, which can impact on the robustness of the model.

In some implementations the predictor 201 could be implemented to make the prediction without any these feedback signals, i.e. without any feedback signal of the filter input voltage Vfilin, the filter output voltage Vfilout or the measured inductor current lind. In others words, the predictor 201 could be implemented as open-loop predictor. In this case, the model may be implemented with predetermined parameters.

However, such an open-loop approach generally requires the pole of the LC filter to be high enough in frequency to allow estimation of the magnetic field strength H as essentially being the integral of the filter input voltage Vfilin (as represented by the input signal Sin). In which case the magnetic field strength H is determined using a leaky integrator with a sufficiently high sample rate and pole below the relevant signal band, e.g. 20 kHz for audio applications.

For some material systems, this may be achievable and the resultant predicted non-linearity may be a reasonable estimate of the actual non-linearity. However, it can, be challenging to account for any change in inductor ripple current with an open-loop predictor and thus a closed loop implementation may be preferred. Note, for implementations where the estimation of the magnetic field strength H as essentially being the integral of the filter input voltage Vfilin (as represented by the input signal Sin) is sufficiently accurate, it may be possible to just supply the feedback signal of the measured inductor current to stabilise operation on the BH curve without the feedback signal of filter output voltage Vfilout.

Referring back to FIG. 2, the predicted error term @ (x) is provided to the corrector 202 which determines the correction term α to be applied to the input signal Sin. As discussed above, the corrector 202 can determine the correction term to any desired order, e.g. zeroth, first, second order etc. The order of correction is a trade-off between computational complexity and residual distortion. For audio applications, it may generally be the case that any strong spectral content that would require a relatively high-order correction to compensate may not actually be audible to the human ear and thus any improvement provided by a relatively high-order correction may be substantially imperceptible. For such audio applications, a first-order or eve zero-order correction may be sufficient suppression of the filter error for other distortions in the amplifier system to dominate. In some embodiments the corrector 202 may be configured to selectively vary the relevant order of the correction term α. Such variation could based on the signal content, e.g. based on some measure of spectral content, and/or to provide a trade-off between power consumption and performance, e.g. in different operating modes.

The correction term α should not be greater than the level of the input signal Sin itself and the magnitude of the correction term may thus, in some implementations, be limited to not exceed a dynamic threshold based on the present level of the input signal, which could, for example, be some fraction of the level of input signal. If the magnitude of the correction term does start to reach the present value of the dynamic threshold, soft limiting may be applied before the dynamic threshold is reached, so as avoid generating artefacts in the drive signal. If the level of the correction term (prior to any limiting) does have a value which is similar to or greater than the present level of the input signal, this may be taken as an indication that the model has failed and is no longer correctly predicting the distortion in the drive signal. If such an eventuality occurs, the corrector 202 may be configured to set the correction term to zero, to avoid making any distortion worse.

Embodiments of the present disclose thus provide compensation circuitry for compensating for distortion of an LC output filter, in particular in the context of a switched mode, or class-D, amplifier system. The compensation circuitry, which may be implemented by a suitable predictor and corrector, may be implemented as part of an integrated circuit (IC) together with at least the modulator of the switched mode-amplifier, so as to provide a correction to the input signal to the modulator. However, it would be possible for the compensation circuitry to be implemented on a separate IC to output a corrected signal as an input to the modulator of the amplifier on a different IC.

The embodiments above have been described in the context of a single-ended amplifier configuration but will be understood that the amplifier could be arranged to drive the load in a bridge-tied-load (BTL) configuration, in which case there may be two LC filters which are both modelled.

Embodiments may be implemented as part of an audio amplifier system, but the principles of the present disclosure may also be used to predict inductor behaviour in other circuit comprising an inductor, for instance in inductive DC-DC converters such as an inductive buck or boost converter or the like. The prediction of inductor behaviour could, for example, be used to determine saturation of the inductor.

Embodiments may be implemented in a host device, which may be a portable and/or battery powered host device such as a mobile computing device for example a laptop, notebook or tablet computer, or a mobile communication device such as a mobile telephone, for example a smartphone. The device could be a wearable device such as a smartwatch. The host device could be a games console, a remote-control device, a home automation controller or a domestic appliance, a toy, a machine such as a robot, an audio player, a video player. It will be understood that embodiments may be implemented as part of a system provided in a home appliance or in a vehicle. There is further provided a host device incorporating the above-described embodiments.

The skilled person will recognise that some aspects of the above-described apparatus and methods may be embodied as processor control code, for example on a non-volatile carrier medium such as a disk, CD- or DVD-ROM, programmed memory such as read only memory (Firmware), or on a data carrier such as an optical or electrical signal carrier. For some applications, embodiments may be implemented on a DSP (Digital Signal Processor), ASIC (Application Specific Integrated Circuit) or FPGA (Field Programmable Gate Array). Thus, the code may comprise conventional program code or microcode or, for example code for setting up or controlling an ASIC or FPGA. The code may also comprise code for dynamically configuring re-configurable apparatus such as re-programmable logic gate arrays. Similarly, the code may comprise code for a hardware description language such as Verilog IM or VHDL (Very high-speed integrated circuit Hardware Description Language). As the skilled person will appreciate, the code may be distributed between a plurality of coupled components in communication with one another. Where appropriate, the embodiments may also be implemented using code running on a field-(re) programmable analogue array or similar device in order to configure analogue hardware.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

1. An apparatus for compensating for distortion in an output drive signal of a switched-mode amplifier which arises from non-linearity of an inductor in an output path for the drive signal, the apparatus comprising:
a distortion predictor configured to predict the distortion in the output drive signal; where the distortion predictor comprises a current predictor configured to determine a predicted current in the inductor based on at least an indication of an input voltage for the inductor, and a model for modelling the distortion based on the predicted current;
a corrector configured to determine a correction term based on the predicted distortion that can be additively applied to an input signal to at least partly compensate for the distortion in the drive signal.

2. The apparatus of claim 1 wherein the indication of an input voltage for the inductor is based on a received input signal for the switched-mode amplifier system.

3. The apparatus of claim 1 wherein the current predictor is configured to determine a predicted current in the inductor based on the indication of an input voltage for the inductor and an indication of an output voltage for the inductor.

4. The apparatus of claim 3 wherein the indication of an input voltage for the inductor is a feedback signal from an input to the inductor and the indication of an output voltage for the inductor is a feedback signal from an output of the inductor.

5. The apparatus of claim 3 wherein the indication of an input voltage for the inductor is based on a received input signal for the switched-mode amplifier system and the indication of an output voltage for the inductor is a feedback signal from an output of the inductor.

6. The apparatus of claim 3 wherein the current predictor is configured to determine the predicted current based on a integral of a voltage difference between the input voltage for the inductor the output voltage for the inductor and an estimate of an inductance of the inductor.

7. The apparatus of claim 6 wherein the current predictor is configured to determine the predicted current based on said integral of the voltage difference for a first frequency range and the current predictor is configured to determine the predicted current based on a feedback signal of a measured average of inductor current for a second, lower, frequency range.

8. The apparatus of claim 6 wherein the current predictor comprises a leaky integrator.

9. The apparatus of claim 6 wherein the model is configured to determine a magnetic field strength of the inductor from the predicted current and to determine a magnetic flux density of the inductor from the magnetic field strength and to update the estimate of the inductance of the inductor.

10. The apparatus of claim 9 wherein the inductor is part of an inductance-capacitance filter with a capacitor and the model is configured to determine a capacitor current through the capacitor and integrate the capacitor current to determine a predicted filter output signal.

11. The apparatus of claim 10 wherein the model is configured to also model non-linearity of the capacitor.

12. The apparatus of claim 1 wherein the current predictor is further configured to determine a predicted current in the inductor based on a feedback signal of a measured average of inductor current.

13. The apparatus of claim 1 wherein the corrector is configured to determine the correction term as a polynomial correction term and wherein an order of the polynomial correction term is selectively configurable.

14. The apparatus of claim 1 wherein the model is configured to be dynamically adapted.

15. An apparatus for compensating for distortion in an output drive signal of a switched-mode amplifier which arises from non-linearity of an inductor in an output path for the drive signal, the apparatus comprising:
a distortion predictor configured to predict the distortion in the output drive signal; and
a corrector configured to determine a correction term based on the predicted distortion that can be additively applied to an input signal to at least partly compensate for the distortion in the drive signal.

16. The apparatus of claim 15 wherein the distortion predictor comprises a current predictor configured to determine a predicted current in the inductor.

17. The apparatus of claim 16 wherein the current predictor is configured as a closed-loop current predictor which receives at least a feedback signal of an output voltage of the inductor.

18. A predictor for predicting a current in an inductor, the current predictor comprising a leaky integrator configured to integrate an indication of a voltage across the integrator and a divider for dividing the output of the integrator by an estimate of an inductance of the inductor.

19. The predictor of claim 18 where the predictor is configured to receive an indication of an input voltage for the inductor and an indication of an output voltage for the inductor and determine said indication of a voltage across the integrator.

20. The predictor of claim 19 wherein the indication of an output voltage for the inductor comprises a feedback signal of a monitored output of the inductor.

21. The predictor of claim 19 wherein the indication of an input voltage for the inductor comprises a feedback signal of a monitored input of the inductor.
